(19) United States
(12) Patent Application Publication
(10) Pub. No.: US 2025/0253008 A1
(43) Pub. Date: Aug. 7, 2025

(54) TESTING CABLE AND TESTING DEVICE

(71) Applicant: Fulian Precision Electronics (Tianjin) Co., LTD., Tianjin (CN)

(72) Inventor: HSIANG-MING HSIEH, New Taipei (TW)

(21) Appl. No.: 18/673,293

(22) Filed: May 23, 2024

(30) Foreign Application Priority Data
Feb. 2, 2024 (CN) 202410151995.5

(51) Int. Cl. G11C 29/56; H01R 12/77; H01R 12/79; H01R 13/642; H01R 31/06

(52) U.S. Cl. CPC G11C 29/56; H01R 12/774; H01R 12/79; H01R 13/642; H01R 31/065; G11C 2029/5602; H01R 2201/06; H01R 2201/20

(57) ABSTRACT

A testing cable for connecting a mother board and a storage card includes a mother board, a storage card, a connecting cable, and a monitor. The mother board connector is used for connecting the mother board. The storage card connector is used for connecting the storage card. The connecting cable is connected to the mother board connector and the storage card connector. The monitor is located on the connecting cable and used for monitoring the connecting cable, the mother board connector, and the storage card connector. When the mother board tests the storage card, the mother board connector is connected to the mother board, and the storage card connector is connected to the storage card. When the testing of the storage card is finished, the storage card is disconnected from the storage card connector. A testing device with the testing cable is also disclosed.

### FIELD

The disclosure herein generally relates to information computing systems, and more particularly relates to a joint module, a server, and a computing system.

### BACKGROUND

When testing storage cards, the storage cards are usually inserted directly into the interface of the mother board, but after the interface is inserted multiple times by storage cards, it may cause damage to the mother board.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a diagram view of an embodiment of a testing device according to the present disclosure.

FIG. 2 is a front view of a testing cable according to the present disclosure.

FIG. 3 is a front view of a mother board connector shown in FIG. 2.

FIG. 4 is a front view of a second connecting terminal and UV light solid glue shown in FIG. 2.

FIG. 5 is a side view of a storage card connector shown in FIG. 2.

FIG. 6 is a front view of the testing cable shown in FIG. 1, showing a monitor located on the testing cable.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

When testing storage cards, the storage cards are usually inserted directly into the interface of a mother board one by one, and after finishing the test, the storage cards need to be removed from the interface of the mother board. However, after the interface is inserted multiple times by storage cards, the interface may be damaged, causing damage to the mother board.

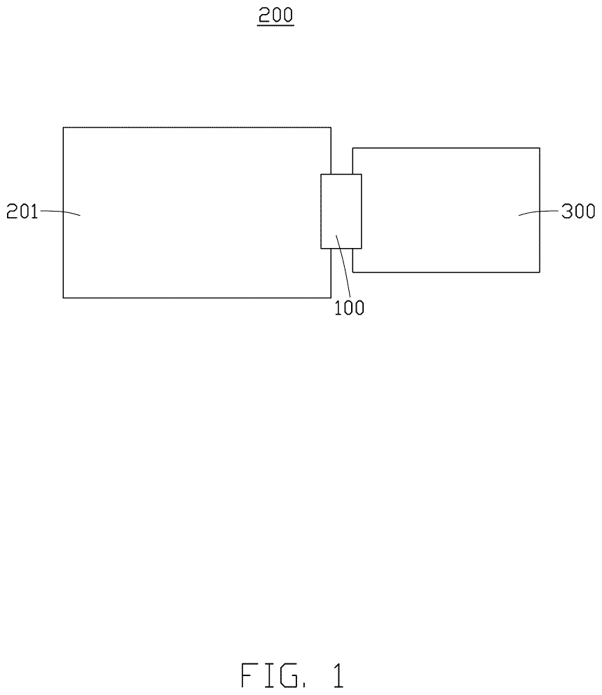

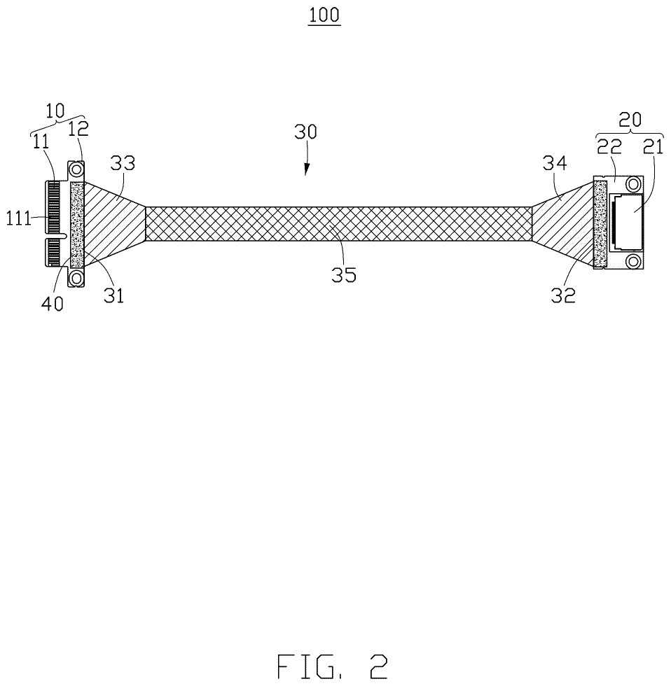

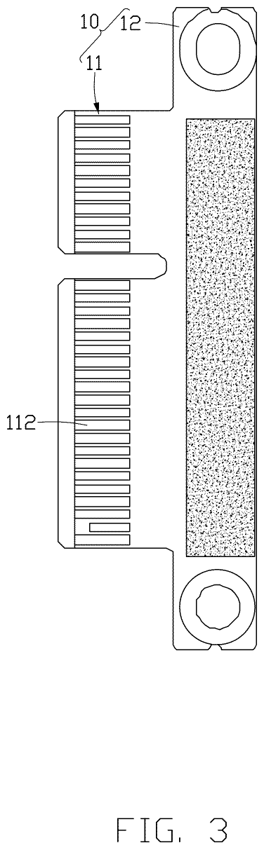

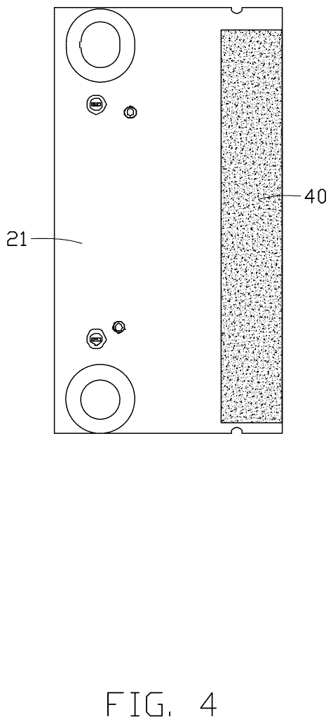

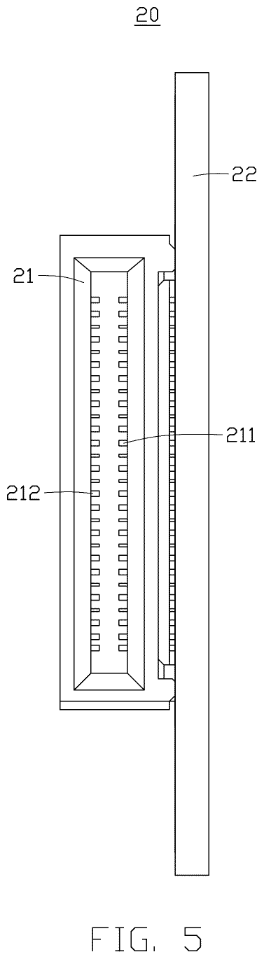

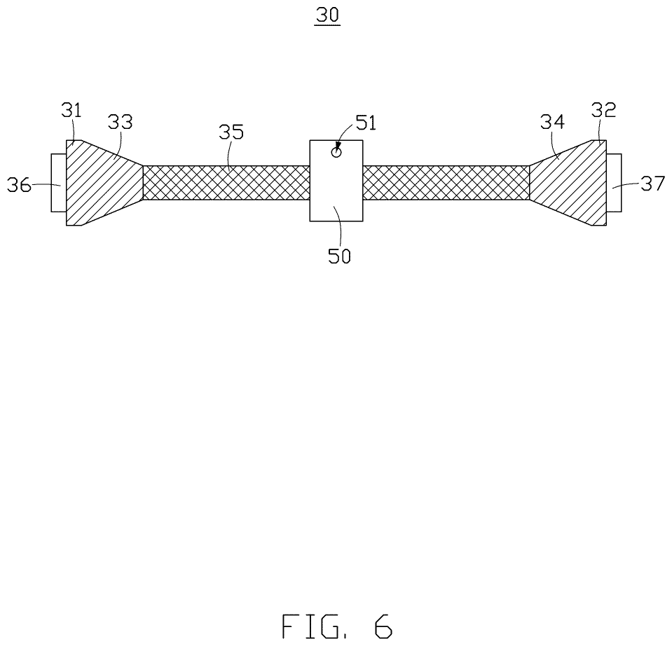

As shown in FIG. 1 to FIG. 6, a testing device 200 in an embodiment includes a mother board 201 and a testing cable 100. The mother board 201 is used for testing the storage card 300. The testing cable 100 has two ends, and one end of the testing cable 100 is connected to the mother board 201, and another end of the testing cable 100 is connected to the storage card 300, so the storage card 300 is connected to the mother board 201 by the testing cable 100. When testing the storage cards 300, the storage cards 300 are only connected to the testing cable 100 one by one, and the testing cable 100 is always connected to the mother board 201, so the storage cards 300 do not need to connect to the mother board 201 directly, avoiding any damage to the mother board 201.

The testing cable 100 includes a mother board connector 10, a storage card connector 20, a connecting cable 30, and a monitor 50. The mother board connector 10 is used for electrically connecting the mother board 201. The storage card connector 20 is used for electrically connecting the storage card 300. The mother board connector 10 is located on one end of the connecting cable 30, and the storage card connector 20 is located on another end of the connecting cable 30. The monitor 50 is located on the connecting cable 30, and used to monitor connecting cable 30, the mother board connector 10, and the storage card connector 20.

When testing the storage card 300, the mother board connector 10 is connected to the mother board 201, the storage card connector 20 is connected to the storage card 300. When testing multiple storage cards 300, just removing the tested storage card 300 from the storage card connector 20, and then plugging another storage card 300 to be tested into the storage card connector 20, and the storage card 300 can be tested, so the storage cards 300 do not need to connect to the mother board 201 directly, avoiding any damage to the mother board 201.

In some embodiments, the mother board connector 10 is a standard PCIe×4 connector, which is peripheral component interconnect express with four lanes.

In some embodiments, the storage card connector 20 is a standard OCP NIC (Open Compute Project Network Interface Card) 3.0 1C connector.

In some embodiments, when the storage card 300 is a standard OPC 1C module board, the OPC 1C module board can connect the OCP NIC 3.0 1C connector (storage card connector 20), to test the OPC 1C module board.

In some embodiments, the mother board connector 10 includes a first connecting terminal 11 and a first installing part 12. The first connecting terminal 11 is used for connecting the mother board 201. The first connecting terminal 11 is connected to the connecting cable 30 by the first installing part 12.

In some embodiments, the first connecting terminal 11 includes a first surface 111 and a second surface 112. The first surface 111 and the second surface 112 face to each other. The first surface 111 and the second surface 112 have 32 pins, respectively. The 32 pins are arranged side by side. The 32 pins of first surface 111 and the 32 pins of the second surface 112 are parallel to each other, and all pins are connected to the end of the connecting cable 30 away from the storage card connector 20.

In some embodiments, the first installing part 12 is made of rubber, plastic, fiber, or other insulating materials, to improve the safety of the connecting cable 30.

In some embodiments, the storage card connector 20 includes a second connecting terminal 21 and a second installing part 22. The second connecting terminal 21 is used for electrically connecting the storage card 300. The second connecting terminal 21 is connected to the connecting cable 30 by the second installing part 22.

In some embodiments, the second connecting terminal 21 includes a third surface 211 and a fourth surface 212. The third surface 211 and the fourth surface 212 have 28 pins, respectively. The 28 pins are arranged side by side. The 28 pins of the third surface 211 and the 28 pins of the fourth surface 212 are parallel to each other. and all pins are connected to the end of the connecting cable 30 away from the first connecting terminal 11.

In some embodiments, the second installing part 22 is made of rubber, plastic, fiber, or other insulating materials, to improve the safety of the connecting cable 30.

In some embodiments, the connecting cable 30 includes a first end 31 and a second end 32. The first end 31 is connected to the first installing part 12 by UV light solid glue 40. The second end 32 is connected to the second installing part 22 by UV light solid glue 40. The UV light solid glue 40 has high bonding strength and fast bonding speed, which facilitates quick connection during the production process of testing cable 100. During the process of plugging and unplugging the mother board connector 10, the connection between the first end 31 and the first installing part 12 and the connection between the second end 32 and second installing part 22 are not easy to separate when subjected to pulling force, which improves the structural strength of the testing cable 100. The UV light solid glue 40 remains flexible after curing, making it easy to test the deformation of cable 100.

In some embodiments, the connecting cable 30 includes a wire harness and a polyethylene tape layer. One end of the wire harness is connected to the first installing part 12, another end of the wire harness is connected to the second installing part 22. The polyethylene tape layer covers the wire harness.

The polyethylene tape refers to an adhesive tape product that uses polyethylene as the base material of the tape and is compounded with adhesive on the other side. The polyethylene tape has excellent chemical stability, water resistance, corrosion resistance, and physical properties, which is beneficial to increasing the service life of the testing cable 100.

In some embodiments, the connecting cable 30 includes a wire harness and a braided cover. One end of the wire harness is connected to the first installing part 12, another end of the wire harness is connected to the second installing part 22. The braided cover covers the wire harness. The braided cover can improve the tear resistance of the wire harness and improve the insulation of the connecting cable 30, reducing the damage of the connecting cable 30 from various light, heat, humidity, low temperature, acid, and alkali gas erosion and external force, thereby ensuring the stable operation of the testing cable 100.

In some embodiments, the connecting cable 30 includes a wire harness, a first polyethylene tape layer 33, a second polyethylene tape layer 34, and a first braided cover 35. One end of the wire harness is connected to the first connecting terminal 11, another end of the wire harness is connected to the second connecting terminal 21. The first polyethylene tape layer 33 covers the end of the wire harness close to the mother board connector 10, and the second polyethylene tape layer 34 covers the end of the wire harness close to the storage card connector 20, and the first braided cover 35 covers the middle part of the wire harness. The first braided cover 35 is located between the first polyethylene tape layer 33 and the second polyethylene tape layer 34, and the first braided cover 35 is connected to the first polyethylene tape layer 33 and the second polyethylene tape layer 34. The first polyethylene tape layer 33, the second polyethylene tape layer 34, and the first braided cover 35 can protect the testing cable 100. For example, the first braided cover 35 is fiber braided cover.

In some embodiments, the connecting cable 30 includes a first plugging part 36 and a second plugging part 37. The first plugging part 36 is located on one end of the connecting cable 30, and the second plugging part 37 is located on another end of the connecting cable 30. The first plugging part 31 is removably connected to the mother board connector 10. The second plugging part 21 is removably connected to the storage card connector 20. When there is any damage to the mother board connector 10 or the storage card connector 20, it is easy to change new mother board connector 10 or new storage card connector 20 to the connecting cable 30.

In some embodiments, the monitor 50 has an indicator light 51. When the connecting cable 30 is functional, the indicator light 51 is light on. When the connecting cable 30 is damaged, the indicator light 51 is light off. Users can determine whether the wire harness is damaged based on the status of indicator light 51.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A testing cable for connecting a mother board and a storage card comprising:
a mother board connector configured for connecting the mother board;
a storage card connector configured for connecting the storage card;
a connecting cable connected to the mother board connector and the storage card connector; and
a monitor located on the connecting cable and configured for monitoring the connecting cable, the mother board connector, and the storage card connector,
wherein when the mother board tests the storage card, the mother board connector is connected to the mother board, and the storage card connector is connected to the storage card, and the storage card is disconnected from the storage card connector after being tested.

2. The testing cable of claim 1, wherein the mother board connector comprises a first connecting terminal and a first installing part, the first connecting terminal is configured for plugging the mother board, the first connecting terminal connects the connecting cable by the first installing part.

3. The testing cable of claim 2, wherein the storage card connector comprises a second connecting terminal and a second installing part, the second connecting terminal is configured for plugging the storage card, the second connecting terminal connects the connecting cable by the second installing part.

4. The testing cable of claim 3, wherein the connecting cable comprises a first end and a second end, the first end is mounted on the first installing part by UV light solid glue, the second end is mounted on the second installing part by UV light solid glue.

5. The testing cable of claim 1, wherein the connecting cable comprises a wire harness and a polyethylene tape layer, the polyethylene tape layer covers the wire harness.

6. The testing cable of claim 1, wherein the mother board connector is a PCIe×4connector, and the storage card connector is an OCP NIC 3.0 1C connector.

7. The testing cable of claim 2, wherein the first connecting terminal comprises a first surface and a second surface, the first surface and the second surface face to each other, the first surface and the second surface comprise thirty-two pins, respectively, the thirty-two pins of the first surface and the thirty-two pins of the second surface are parallel to each other, and all pins are connected to an end of the connecting cable away from the storage card connector.

8. The testing cable of claim 3, wherein the second connecting terminal comprise a third surface and a fourth surface, the third surface and the fourth surface comprise twenty-eight pins, respectively, the twenty-eight pins of the third surface and the twenty-eight pins of the fourth surface are parallel to each other, and all pins are connected to an end of the connecting cable away from the mother board connector.

9. The testing cable of claim 5, wherein the monitor is electrically connected to the wire harness, the monitor comprises a indicator light, when the connecting cable is functional, the indicator light is light on, and when the connecting cable 30 is unfunctional, the indicator light is light off.

10. The testing cable of claim 1, wherein the connecting cable comprises a first plugging part and a second plugging part, the first plugging part is removably connected to the mother board connector, the second plugging part is removably connected to the storage card connector, the mother board connector and the storage card connector are replaceable on the connecting cable.

11. A testing device comprising:
a mother board configured for testing a storage card; and
a testing cable connected between the mother board and the storage card, wherein the testing cable comprises:
a mother board connector configured for connecting the mother board;
a storage card connector configured for connecting the storage card;
a connecting cable connected to the mother board connector and the storage card connector; and
a monitor located on the connecting cable and configured for monitoring the connecting cable, the mother board connector, and the storage card connector, wherein when the mother board tests the storage card, the mother board connector is connected to the mother board, and the storage card connector is connected to the storage card, and the storage card is disconnected to the storage card connector after being tested.

12. The testing device of claim 11, wherein the mother board connector comprises a first connecting terminal and a first installing part, the first connecting terminal is configured for plugging the mother board, the first connecting terminal connects the connecting cable by the first installing part.

13. The testing device of claim 12, wherein the storage card connector comprises a second connecting terminal and a second installing part, the second connecting terminal is configured for plugging the storage card, the second connecting terminal connects the connecting cable by the second installing part.

14. The testing device of claim 13, wherein the connecting cable comprises a first end and a second end, the first end is mounted on the first installing part by UV light solid glue, the second end is mounted on the second installing part by UV light solid glue.

15. The testing device of claim 11, wherein the connecting cable comprises a wire harness and a polyethylene tape layer, the polyethylene tape layer covers the wire harness.

16. The testing device of claim 11, wherein the mother board connector is a PCIe×4connector, and the storage card connector is an OCP NIC 3.0 1C connector.

17. The testing device of claim 12, wherein the first connecting terminal comprises a first surface and a second surface, the first surface and the second surface face to each other, the first surface and the second surface comprise thirty-two pins, respectively, the thirty-two pins of the first surface and the thirty-two pins of the second surface are parallel to each other, and all pins are connected to an end of the connecting cable away from the storage card connector.

18. The testing device of claim 13, wherein the second connecting terminal comprise a third surface and a fourth surface, the third surface and the fourth surface comprise twenty-eight pins, respectively, the twenty-eight pins of the third surface and the twenty-eight pins of the fourth surface are parallel to each other, and all pins are connected to an end of the connecting cable away from the mother board connector.

19. The testing device of claim 15, wherein the monitor is electrically connected to the wire harness, the monitor comprises a indicator light, when the connecting cable is functional, the indicator light is light on, and when the connecting cable 30 is unfunctional, the indicator light is light off.

20. The testing device of claim 11, wherein the connecting cable comprises a first plugging part and a second plugging part, the first plugging part is removably connected to the mother board connector, the second plugging part is removably connected to the storage card connector, the mother board connector and the storage card connector are replaceable on the connecting cable.
